(19) United States
(12) Patent Application Publication
(10) Pub. No.: US 2026/0107771 A1
(43) Pub. Date: Apr. 16, 2026

(54) Optical Transmitter

(71) Applicant: NTT, Inc, Tokyo (JP)

(72) Inventors: Josuke Ozaki, Musashino-shi, Tokyo (JP); Yoshihiro Ogiso, Musashino-shi, Tokyo (JP); Mitsuteru Ishikawa, Musashino-shi, Tokyo (JP)

(21) Appl. No.: 19/115,364

(22) PCT Filed: Oct. 3, 2022
(86) PCT No.: PCT/JP2022/037030

§ 371 Date: Mar. 26, 2025

(51) Int. Cl. H10W 40/28; G02B 6/42; G02F 1/015; H04B 10/50; H10W 90/00

(52) U.S. Cl. CPC H10W 40/28; G02B 6/4271; G02F 1/015; H04B 10/501; G02B 6/4206; G02F 2202/102; H10W 90/753; H10W 90/755

(57) ABSTRACT

Disclosed is a new configuration for improving temperature dependency of optical modulation output characteristics, and an implementation form adapted to each configuration in an optical transmitter in which an optical modulator and a driver IC thereof are integrally packaged. The optical transmitter includes: an optical modulator; a driver integrated circuit (driver IC) for supplying a modulation electrical signal for the optical modulator; a first Peltier device for controlling a temperature of the optical modulator; and a second Peltier device for controlling a temperature of the driver IC, in which the optical modulator and the driver IC are connected by a wire, and the temperature of the second Peltier device is set to be lower than the temperature of the first Peltier device.

### TECHNICAL FIELD

The present invention relates to an optical transmitter used in optical communication. More particularly, the present invention relates to an implementation form of an optical transmitter including a semiconductor optical modulator and a driver IC thereof.

### Background Art

In order to cope with a rapid traffic increase of a communication network, digital coherent optical transmission combining a coherent communication scheme and a digital signal processing technology has been introduced into an optical fiber communications system. Starting from the establishment of a backbone network transmission technology of 100 Gbps per wavelength at the beginning, transmission of 400 Gbps to 600 Gbps per wavelength, which is faster, has been put into practical use at present.

In the above-described digital coherent optical transmission, an optical transmission/reception device in which an optical receiver and an optical transmitter are integrated is used. In the optical transmission/reception device of a system having a transmission capacity exceeding 400 Gbps, an analog component such as a radio frequency (RF) electric circuit is required to have a wide bandwidth. For example, in an optical modulator, a modulation bandwidth of 40 GHz or more is required. In order to reduce a high-frequency loss and downsize a device, which leads to having a wide bandwidth, for example, a form in which an RF driver IC and an optical modulator are mounted in an integrated package on a transmission side has attracted attention. An implementation form of this optical transmitter is also standardized by the Optical Internetworking Forum (OIF) under the name of High-Bandwidth Coherent Driver Modulator (HB-CDM) (Non Patent Literature 1). On a reception side of the optical transmission/reception device, a transimpedance amplifier (TIA) and an optical receiver are mounted in an integrated package, which is also referred to as an integrated coherent receiver (ICR).

Turning to materials for an optical transmitter/receiver device, a semiconductor-based optical modulator has attracted attention instead of a conventional lithium niobate (LN) optical modulator in terms of miniaturization and cost reduction. For higher-speed modulation operation, a compound semiconductor represented by InP is mainly used. Furthermore, research and development are concentrated on a Si-based optical device in a system with emphasis on miniaturization and cost reduction.

There are advantages and disadvantages inherent to materials in the above-described semiconductor-based optical modulator, and for example, in an InP optical modulator, temperature control of an optical modulator chip is essential during operation in order to control a band-edge absorption effect. On the other hand, the Si optical modulator has a merit that the temperature control is unnecessary, but has a smaller electro-optical effect than other material systems. For this reason, it is necessary to increase the electro-optical interaction length, and as a result of increasing the device length, a high-frequency loss may be increased. There are many problems in achieving the higher speed and wide bandwidth of the optical modulator in addition to the implementation technology for the wide bandwidth and miniaturization.

The operation temperature (case temperature) of the optical transmitter with the HB-CDM is required to be in a range of at least −5° C. to 75° C. In order to obtain the operation temperature, generally, only the optical modulator chip is mounted on a Peltier device in consideration of power consumption (Patent Literature 1).

### Citation List

### Patent Literature

Patent Literature 1: WO 2021/171599 A

### Non Patent Literature

Non Patent Literature 1: OIF, Implementation Agreement for the High Bandwidth Coherent Driver Modulator (HB-CDM), [online], Jul. 15, 2021, [retrieved on Sep. 1, 2022], Internet <URL: https://www.oiforum.com/wp-content/uploads/OIF-HB-CDM-02.0.pdf>

Non Patent Literature 2: J. Ozaki et al., “500-Gb/s/λ Operation of Ultra-Low Power and Low-Temperature-Dependence InP-Based High-Bandwidth Coherent Driver Modulator,” in Journal of Lightwave Technology, vol. 38, no. 18, pp. 5086-5091, 15 Sep. 15, 2020, doi: 10.1109/JLT.2020.2998466.

### SUMMARY OF INVENTION

### Technical Problem

However, in the optical transmitter of the related art, deterioration of high-frequency characteristics of the driver IC at a high temperature has been a problem. Specifically, in a case where the environmental temperature is high, there has been a problem that the high frequency bandwidth, peaking amount, and gain of the driver IC deteriorate. In achieving the speed increase and wide bandwidth of the optical transmitter, the influence of a decrease in signal quality due to the above-described deterioration cannot be ignored. Therefore, an optical transmitter capable of maintaining a constant high-frequency characteristics regardless of a change in an environmental temperature is desired.

In view of the above-described problems, the present invention provides a novel configuration and an implementation form of an optical transmitter that suppresses temperature dependency of an optical transmitter including a driver IC, is excellent in speed, and is capable of stably operating regardless of the environmental temperature.

### Solution to Problem

According to one aspect of the present invention, there is provided an optical transmitter including: an optical modulator; a driver integrated circuit (driver IC) for supplying a modulation electrical signal for the optical modulator; a first Peltier device for controlling a temperature of the optical modulator; and a second Peltier device for controlling a temperature of the driver IC, in which the optical modulator and the driver IC are connected by a wire, and the temperature of the second Peltier device is set to be lower than the temperature of the first Peltier device.

### Advantageous Effects of Invention

In view of the above-described problems, the present invention provides a novel configuration and an implementation form of an optical transmitter that suppresses temperature dependency of an optical transmitter including a driver IC, is excellent in speed, and is capable of stably operating regardless of the environmental temperature.

### BRIEF DESCRIPTION OF DRAWINGS

FIG. 1 is a side cross-sectional view illustrating an implementation form of an optical transmitter using an HB-CDM of the related art.

FIG. 2 is a side cross-sectional view illustrating an implementation form of an optical transmitter using an HB-CDM of the present invention.

FIG. 3 is a diagram for describing a restriction of a wire connection portion in a height direction in an optical transmitter.

FIG. 4 is a side cross-sectional view illustrating another implementation form of an optical transmitter using an HB-CDM of the present invention.

FIG. 5 is a diagram for describing a restriction of a pad position and the like in a circuit plane of an optical transmitter.

FIG. 6 is a diagram for describing density arrangement of a Peltier device in the optical transmitter of the present invention.

### DESCRIPTION OF EMBODIMENTS

The present invention presents a new configuration for improving temperature dependency of high-frequency characteristics of an optical transmitter, and an implementation form adapted to each configuration in an optical transmitter in which an optical modulator and a driver IC thereof are integrally packaged. The configuration for improving the temperature dependency includes a new application form of a temperature regulator (thermoelectric cooler (TEC)) in the optical transmitter. Moreover, various implementation forms of a driver IC, an optical modulator chip and a spatial optical component, which are adapted to a new application form of the TEC are also proposed.

The TEC is also called a thermoelectric cooler, and is known as a small cooling device by Peltier junction. The TEC includes an n-type semiconductor, a p-type semiconductor, and a metal, and when a direct current flows through both surfaces of an element formed in a plate shape, heat absorption occurs on one surface and heat dissipation occurs on the other surface. When the direction of the current is reversed, the heat absorption and the heat dissipation are switched. Therefore, local and accurate temperature control for the IC and the electronic component is possible. In the following description, the temperature regulator is referred to as a TEC for simplicity, and will be described as a Peltier device. As long as the temperature of the driver IC or the optical modulator chip can be controlled, the present invention is not limited to the Peltier device.

In the following, the problem of the temperature dependency of the high-frequency characteristics in the optical transmitter will be first described with an optical modulator using the HB-CDM of the related art as an example. Thereafter, a novel configuration for improving the temperature dependency of the high-frequency characteristics with the optical transmitter of the present invention will be described together with various implementation forms.

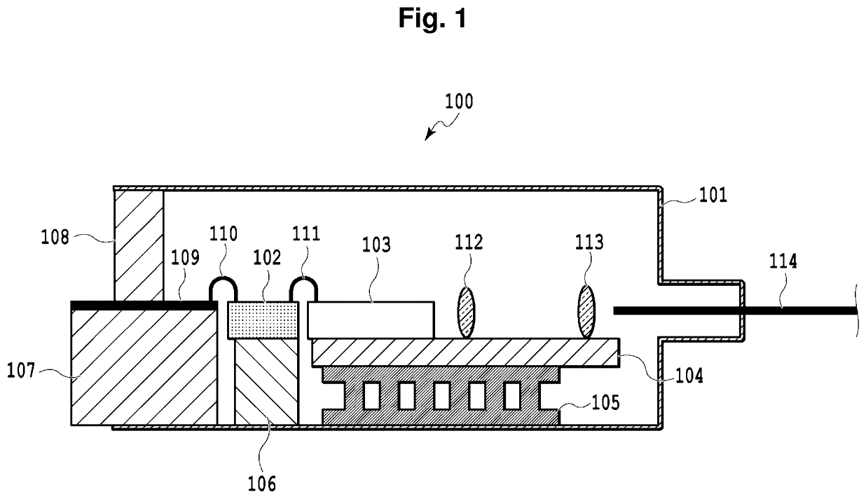

FIG. 1 is a side cross-sectional view illustrating an implementation form of the optical transmitter using the HB-CDM of the related art. In an optical transmitter 100, a driver IC 102, an optical modulator chip 103, lenses 112 and 113 which are spatial optical components, and the like are housed inside a package housing 101 made of ceramic, metal, or the like, or a combination thereof, according to the specification of the HB-CDM. More specifically, the optical modulator chip 103 is mounted on the bottom surface inside the housing 101 via a subcarrier 104 on a Peltier device 105. At the right end of the optical modulator chip 103 in the drawing, there is an emission end face of the modulation light, and the lenses 112 and 113 for optically coupling the modulation light with an optical fiber 114 are also mounted on the subcarrier.

The driver IC 102 is mounted on a metal block or a ceramic member 106 adjacent to the optical modulator chip 103. Moreover, a wiring board base 107 and a package wall surface 108 are provided as wall surfaces on the left side of the package housing 101 in the drawing, and define the outside and the internal space of the optical transmitter together with the package housing 101. The optical transmitter 100 can be configured such that the entire package ensures airtightness.

A modulation electrical signal supplied from an external digital signal processor (DSP) is supplied to the optical modulator chip 103 via a wiring layer 109 of the wiring board base 107 and the driver IC 102. The wiring layer 109 and the driver IC 102, and the driver IC 102 and the optical modulator chip 103 are connected by gold wire lines 110 and 111, respectively. In a case of the polarization multiplexing type IQ optical modulation scheme, the modulation electrical signal includes an I channel and a Q channel for X polarization and Y polarization. In a case where one channel is supplied as a differential signaling electrical signal, at least eight signal wirings and a GND wiring are required for one optical modulator, but the modulation signaling is not limited thereto. As described in Patent Literature 1, the optical transmitter 100 illustrated in FIG. 1 is mounted on a common device substrate together with an ICR package or a DSP in which the TIA and the optical receiver on the reception side are integrated, and can constitute an optical transmission/reception device.

Here, attention is again focused on the Peltier device 105 in the optical transmitter. Temperature control is essential for the optical modulator chip 103 prepared on an InP substrate, and the temperature is controlled to a predetermined operation temperature by the Peltier device 105. As illustrated in FIG. 1, the Peltier device 105 has a size that covers at least the entire region of the optical modulator chip 103, and its position may overlap a region of the spatial optical component such as a lens. On the other hand, in the optical transmitter 100 of the related art, it is considered that the temperature control of the driver IC 102 is not necessary, and the optical transmitter is fixed in the package by a member 106 such as a metal block or a ceramic member. When the external temperature (environmental temperature) of the optical transmitter 100 increases, the increased temperature becomes the operation temperature of the driver IC 102. Actually, since the driver IC is also a heating element, in consideration of heat generation from the driver, it is estimated that the operation temperature of the driver IC is higher than the external temperature by about +5° C. to 10° C. When the maximum environmental temperature at which the optical transmission/reception device including the optical transmitter is used is 85° C., the temperature of the driver IC 102 itself is at least 85° C. or higher. The driver IC also has large power consumption, and the driver IC itself generates heat. This means that the back side temperature of the driver IC exceeds the maximum environmental temperature of 85° C. due to the influence of heat generation of the driver IC.

The driver IC has temperature dependency of amplification characteristics (high-frequency characteristics) of a radio frequency electrical signal, and in a high temperature state, a high frequency bandwidth tends to decrease as compared with a room temperature state. Conversely, in a low temperature state, the high frequency bandwidth tends to increase as compared with the room temperature state. As described above, the high-frequency characteristics of the driver IC are different between the low temperature state and the high temperature state. The modulation signal supplied to the driver IC is variously optimized and compensated by the DSP in the room temperature state. However, performing such compensation while dynamically performing update with temperature variation is complicated processing and is not generally performed. Since the operation is continued in a constant compensation state at the room temperature, the compensation state of the modulation signal deviates from the optimum point when the state changes to the low temperature state or the high temperature state. Therefore, optical transmission characteristics and waveform quality of the optical transmitter fluctuate or deteriorate.

The IQ modulator of the optical modulator chip 103 is a linear modulator that preserves the amplitude and phase of the electrical signal, and variations in the level and waveform quality of the modulation electrical signal directly affect the quality of the modulation output light. When the external temperature changes during the operation of the optical transmitter, the optical modulator chip itself is maintained at a constant temperature since the temperature is controlled by the Peltier device, but the operation temperature of the driver IC changes.

As a result, there is also a problem that a level variation and a quality variation of the modulation light of the HB-CDM occur, and since the environmental temperature temporally changes, transmission characteristics are deteriorated and are not stable.

The characteristic deterioration caused by the environmental temperature on the high-frequency band of the electrical signal causes waveform distortion of the modulation signal, and the modulation accuracy of the modulation output light from the optical modulator is deteriorated. In the optical receiver that receives such deteriorated modulation light, a BER floor appears in BER characteristics, which leads to deterioration of transmission characteristics of a system.

The influence of deterioration of the high-frequency characteristics of the driver IC at high temperature as described above cannot be ignored in a situation where a modulation bandwidth of 40 GHz or more is required as the request for widening the bandwidth of the modulation electrical signal is made. The present invention presents a new configuration and an implementation form for improving temperature dependency in high-frequency characteristics and optical transmission characteristics in the optical transmitter in which the optical modulator and the driver IC thereof are integrally packaged.

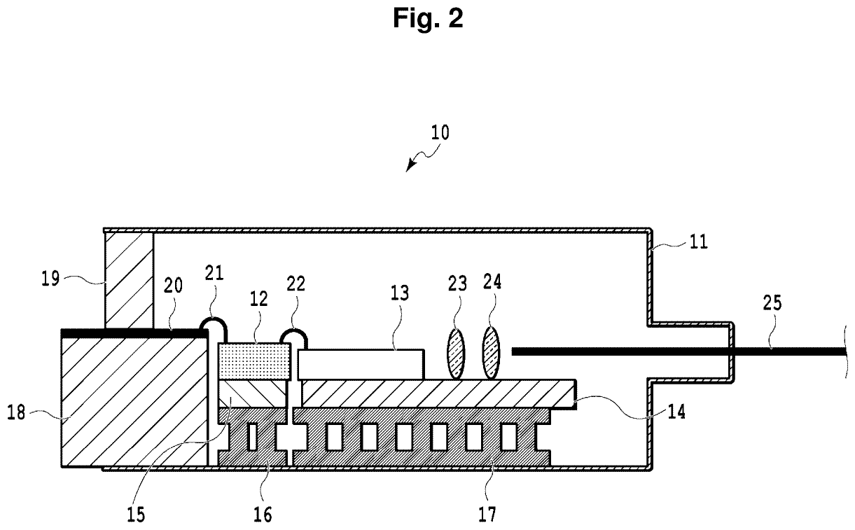

FIG. 2 is a side cross-sectional view illustrating an implementation form of the optical transmitter using the HB-CDM of the present invention. In an optical transmitter 10 of the present invention, similarly to the configuration of the related art illustrated in FIG. 1, an optical modulator chip 13 made of InP, a driver IC 12 thereof, and the like are integrated in a package housing 11 for the HB-CDM. A wiring board base 18 and a package wall surface 19 are provided as wall surfaces on the left side of the package housing 11 in the drawing, and the inside and the outside of the package are defined similarly to FIG. 1. A difference from the configuration of the related art in FIG. 1 is an application form of the TEC that performs temperature control, that is, the Peltier device. Unlike the application form of the Peltier device in FIG. 1, the driver IC 12 is also mounted on a Peltier device 16. The second Peltier device 16 of the driver IC 12 is separate and independent from a Peltier device 17 that performs temperature control of the optical modulator chip 13, and the optical transmitter 10 includes two Peltier devices.

The optical modulator chip 13 and lenses 23 and 24 are mounted on the Peltier device 17 via a subcarrier 14. The subcarrier 14 functions as a base for fixing and holding the optical modulator chip and the spatial optical component. Furthermore, wiring for connecting to a DC wiring of the optical modulator chip, a positioning marker for mounting the spatial optical component, and the like are formed on the subcarrier 14 by a metal pattern.

It is desirable that a material of the subcarrier 14 is excellent in thermal conductivity since the optical modulator chip 13 to be subjected to temperature control is mounted. Specifically, a ceramic substrate such as an AlN substrate is preferable. Since the AlN substrate has a material constant close to that of InP, the AlN substrate is compatible with the optical modulator using InP also in terms of behavior with respect to temperature change. From the same reason and the viewpoint of material consistency, it is desirable that the ceramic member on the upper surface of the Peltier device 17 is also composed of AlN. In FIG. 2, the subcarrier 14 is illustrated as being composed of AlN having a one-layer structure, but may be a multilayer AlN substrate. In a case where the number of DC wirings provided to the optical modulator is large, or in a case where it is necessary to perform cross wiring for switching the order of terminals, it is possible to make a flexible element/wiring layout using a multilayer wiring by using the multilayer substrate.

The driver IC 12 whose temperature is controlled independently of the optical modulator chip 13 is also desirably mounted on the Peltier device 16 via a holding member 15 in order to align the height with a RF terrace corresponding to the upper surfaces of the optical modulator chip 13 and the wiring board base 18. As the holding member 15, a metal block, a ceramic substrate, or the like can be used. In consideration of thermal conductivity, for example, in a case where the DC wiring is unnecessary in the driver IC 12, a metal block such as a CuW block can be used, and in a case where the DC wiring of the driver is necessary, a ceramic such as an AlN substrate can also be used. In a case where the AlN substrate is used, the number of wirings provided to the driver IC is large, and the wiring is complicated, a multilayer substrate can also be used similarly to the subcarrier 14 of the optical modulator chip described above.

As described above, the driver IC is a heating element, and is not considered as an object to be temperature-controlled by the Peltier device. Driving power is required to operate the Peltier device, and it is not considered to use extra power for the heating element. However, in order to realize the wide bandwidth of the optical transmitter, the inventors have made a new idea of controlling the temperature of the heating element.

The optical transmitter 10 of the present invention includes the two Peltier devices 16 and 17 that are independently controlled as described above, such that the temperature of the optical modulator chip 13 and the temperature of the driver IC 12 can be independently controlled. Although not explicitly illustrated in FIG. 2, two Peltier devices are connected to separate control current sources. For a specific control temperature of each part, the InP optical modulator is desirably used generally at about 45±10° C. since the modulation efficiency decreases when the temperature is too low.

On the other hand, for the driver IC 12, it is known that the high-frequency characteristics are better in the low temperature state than in the high temperature state, and it is desirable as the set temperature is lower. However, even when the set temperature is too low, the improvement of the high-frequency characteristics of the driver IC is limited while the power consumption in the Peltier device is increased. Therefore, for example, it is most appropriate to operate the driver IC at 30±10° C. near room temperature from the viewpoint of achieving both power consumption and high-frequency characteristics. By independently setting the optical modulator chip 13 and the driver IC 12 to different temperatures, it is possible to realize an optical transmitter that can operate in an optimum state for each of the optical modulator chip 13 and the driver IC 12.

Therefore, the optical transmitter 10 of the present invention includes an optical modulator 13, a driver integrated circuit (driver IC) 12 for supplying a modulation electrical signal for the optical modulator, a first Peltier device 17 for controlling a temperature of the optical modulator, and a second Peltier device 16 for controlling a temperature of the driver IC, and can be implemented as an optical transmitter such that the optical modulator and the driver IC are connected by a wire and the temperature of the second Peltier device is set to be lower than the temperature of the first Peltier device.

Between the members whose temperatures are controlled by the Peltier devices, it is necessary to mount a conductive paste or solder having thermal conductivity of 30 W/mK or more and excellent thermal conductivity in order to improve heat dissipation by the Peltier device. For the management of the manufacturing process temperature and the like of a module, the same conductive paste and solder may be used, or those having different fixing temperatures and the like may be used in combination.

All the spatial optical components such as the lenses 23 and 24 are mounted on the Peltier device 17 in order to suppress the thickness variation of an adhesive due to a temperature change. Thus, it is possible to minimize fluctuation of the optical insertion loss and the like caused by the deviation of the optical axis due to the temperature change. Note that examples of the spatial optical component include a fiber fixing member, and a polarization beam combiner (PBC).

Although FIG. 2 illustrates the optical transmitter 10 using the HB-CDM as an example, the same effect can be obtained even in the case of using other package forms as long as an optical transmission module is constituted in which the driver IC and the optical modulator are integrally configured. Furthermore, FIG. 2 illustrates an example in which a wiring from a DSP that supplies a modulation signal to the driver IC 12 is connected on the RF terrace by a flexible printed circuit (FPC). That is, a metal pattern 20 on the upper surface of the wiring board base 18 outside the optical transmitter is connected to an FPC cable (not illustrated). Since a FPC interface does not require an RF via (VIA) or the like as compared with a configuration using a surface mount technology (SMT), the FPC interface is excellent in high-frequency characteristics.

Next, a mounting structure for ensuring high-frequency characteristics of the driver IC, the optical modulator, and the like will be described. In the optical transmitter 10 using the HB-CDM illustrated in FIG. 2, the electrode pad of the driver IC and the electrode pad of the RF terrace, and the electrode pad of the driver IC and the electrode pad of the optical modulator are connected by wires 21 and 22, respectively. When a wire is long, a series inductance component increases, and thus a roll-off frequency in the high-frequency characteristics shifts to the low-frequency side due to LC resonance. Therefore, in order to suppress deterioration of high-frequency characteristics in the driver IC and realize a smooth connection, the inductance of the wire is desirably low. Thus, in the optical transmitter 10, the height direction and the planar direction of each unit to be wire-connected are defined.

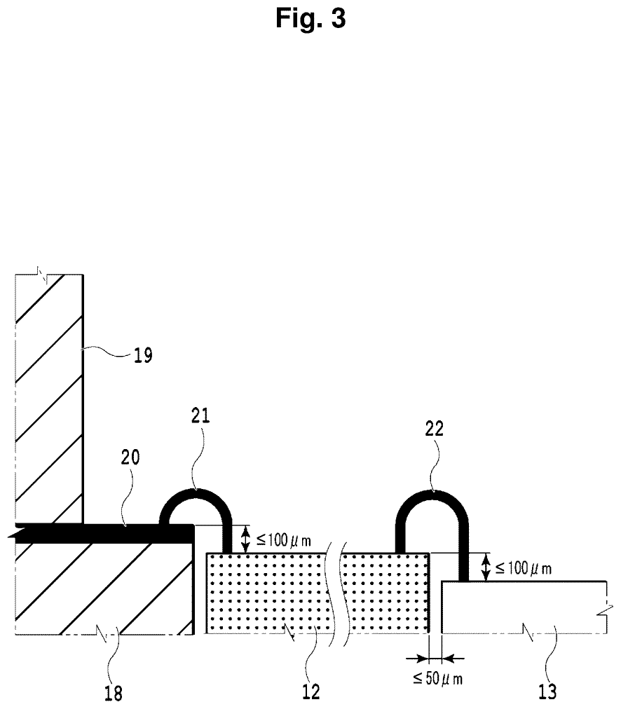

FIG. 3 is a diagram for describing a restriction of a wire connection portion in the height direction in the optical transmitter. In FIG. 2, the vicinity of the electrode 20 of the RF terrace and the vicinity of the upper surfaces of the driver IC 12 and optical modulator chip 13 are enlarged in the height direction. In the height difference between the pads connected by the wire, the height difference between the electrode pad of the driver IC and the electrode pad of the RF terrace, and the height difference between the electrode pad of the driver IC and the electrode pad of the optical modulator are respectively 100 μm or less. This limitation is the minimum range that can be realized in consideration of the thickness variation of each chip and the variation of the mounting member such as the subcarrier.

Gap limitation (≤50 μm) between the driver IC 12 and the optical modulator chip 13 illustrated in FIG. 3 in a circuit in-plane direction will be described later. In FIG. 2, the driver IC 12 and the optical modulator chip 13 are disposed such that sides are parallel to each other, and are mounted so as to overhang from members immediately below the driver IC 12 and the optical modulator chip 13. That is, one side of the driver IC 12 is mounted to protrude toward the optical modulator chip 13 with respect to the holding member 15 of the member immediately below the driver IC in the circuit plane, and one side of the chip of the optical modulator is mounted to protrude toward the driver IC 12 with respect to the subcarrier 14 immediately below the chip in the circuit plane. The above-described mounting configuration in which the IC or the chip overhangs is provided to prevent the fixing adhesive or the like from warping up on the upper surface of the IC or the chip. In the optical transmitter of the present invention, the temperature control of the driver IC by the Peltier device greatly contributes to the effect of improving the temperature dependency in the high-frequency characteristics and the optical transmission characteristics. Although a specific example of overhanging mounting will be described below, when there is a technology capable of performing parallel wire mounting without a difference in height between pads, the difference between the wire connection portions in the height direction illustrated in FIG. 3 may not be essential in some cases. Furthermore, the overhang mounting may not be essential depending on other structures and methods that can well control warpage of the adhesive or the like.

For example, in the case of a design in which the thickness of the optical modulator chip is 300 μm and the thickness of the driver IC is 300 μm and the heights of the two Peltier devices 16 and 17 are the same, when the holding member 15 and the subcarrier 14 are set to have the same height, the height of the pad on the upper surface of the driver IC and the height of the pad on the upper surface of the optical modulator chip are the same. However, in order to minimize the wire length, it is best to reduce the thickness of the subcarrier on the optical modulator chip side by about 50 μm and mount the wire so as to be laid from the optical modulator side to the driver IC side. Similarly, between the electrode pad of the driver IC and the electrode pad of the RF terrace, it is desirable to optimize the height of the holding member 15 under the driver IC and the height of the Peltier device 16 such that the upper surface of the driver IC is slightly lower than the RF terrace portion.

For example, in the case of a design in which the thickness of the driver IC 12 is significantly thin such as 100 μm and the thickness of the optical modulator chip is 300 μm and the heights of the two Peltier devices 16 and 17 are the same, when the holding member 15 and the subcarrier 14 are set to have the same height, the height difference of 200 μm is generated on the upper surfaces of two chips. In such a case, it is necessary to adjust the height of the holding member 15 and the height of the subcarrier 14. For example, when a 250 μm metal block is additionally mounted under the driver IC, the height of the upper surface of the driver IC 12 from the common upper surface position of the Peltier device is 350 μm, and the height of the upper surface of the optical modulator chip is 300 μm. As a result, the difference in height between the driver IC 12 and the optical modulator chip becomes 50 μm, and an ideal state in which the upper surface of the driver IC is located at a higher position can be formed. Note that the height of the RF terrace needs to be adjusted in accordance with height of the upper surface of the driver IC 12.

It should be noted that, as described above, when a technology capable of wire-mounting of the pads having the same height becomes available, the difference in height among the upper surfaces of the RF terrace, driver IC, and optical modulator chip described above may become unnecessary in some cases.

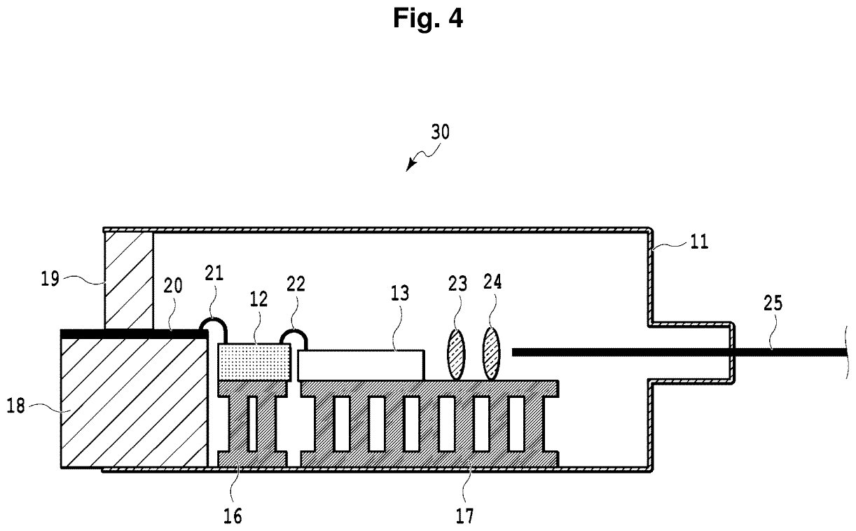

FIG. 4 is a side cross-sectional view illustrating another implementation form of the optical transmitter using the HB-CDM of the present invention. An optical transmitter 30 has a configuration in which the number of members is reduced for cost reduction as compared with the optical transmitter 10 illustrated in FIG. 2, and the driver IC 12 and the optical modulator chip 13 are directly mounted on the Peltier devices 16 and 17, respectively. As described with reference to FIG. 3, the holding member 15 and the subcarrier 14 whose heights can be adjusted are omitted. In the case of the simplified configuration as illustrated in FIG. 4, it is also possible to adjust the height difference in each chip upper surface by changing the heights of the two Peltier devices 16 and 17. In the configuration of the optical transmitter 30 illustrated in FIG. 4, the number of members and a portion requiring an adhesive are reduced, and thus improvement of thermal resistance through reduction of the adhesive portion and reduction of power consumption associated therewith can be expected.

Also in FIG. 4, the driver IC 12 and the optical modulator chip 13 are disposed such that sides are parallel to each other, and are mounted so as to overhang from members immediately below the driver IC 12 and the optical modulator chip 13. That is, one side of the driver IC 12 is mounted to protrude toward the optical modulator chip 13 with respect to the Peltier device 16 which is the member immediately below the driver IC in the circuit plane, and one side of the chip of the optical modulator is mounted to protrude toward the driver IC 12 with respect to the Peltier device 17 immediately below the chip in the circuit plane. Also in FIG. 4, the temperature control of the driver IC by the Peltier device greatly contributes to the effect of improving the temperature dependency in the high-frequency characteristics and the optical transmission characteristics. Therefore, even when there is no difference between the wire connection portions in the height direction in FIG. 3 or there is no overhang mounting in FIG. 4, it is possible to realize an optical transmitter capable of stable operation regardless of the environmental temperature.

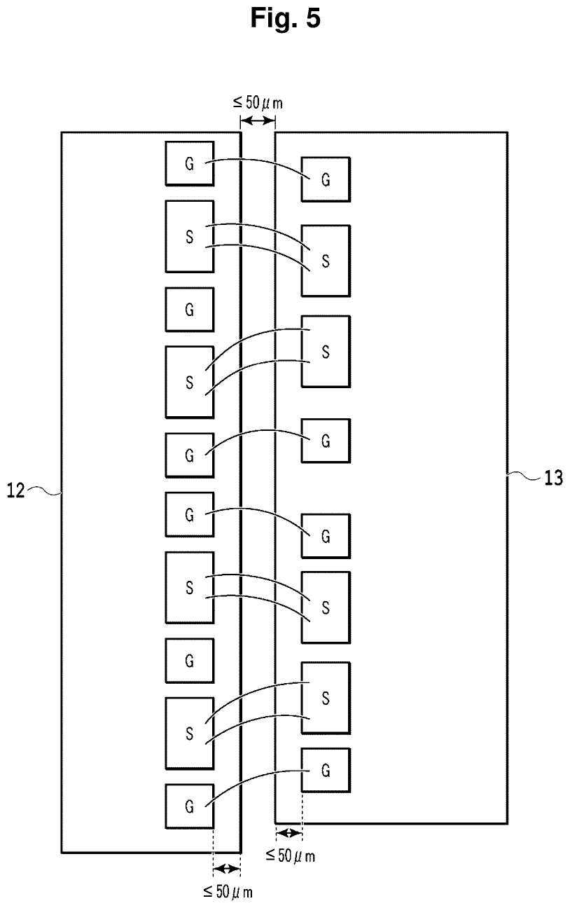

FIG. 5 is a diagram for describing a restriction of the pad or the like in the circuit plane of the optical transmitter. Since the gap between the optical modulator chip 13 and the driver IC 12 in the circuit plane directly corresponds to the length of the wire, it is desirable to minimize the gap between two chips. In consideration of workability in a mounting process and the risk of a short circuit, it is desirable to control the gap to be 50 μm or less. Furthermore, even in a case where only the gap between the two chips is controlled, when the electrode pad is formed at a place away from the chip end, there is no effect on shortening the wire length. Therefore, a distance to the electrode pad is set to be 50 μm or less from each chip end. When the distance from the chip end to the electrode pad is 50 μm or less, it is a value that can be sufficiently realized by a normal dicing or a cleavage process. That is, as illustrated in FIG. 2 and FIG. 4, one side of the driver IC is mounted to protrude toward the chip side of the optical modulator with respect to the member immediately below the driver IC in the circuit plane, and one side of the chip of the optical modulator is mounted to protrude toward the driver IC with respect to the member immediately below the chip in the circuit plane.

FIG. 5 illustrates, as an example, an output electrode pad on the driver IC side and an input electrode pad on the optical modulator chip side. Although the output electrode pad on the driver IC side is GSGSG and the input electrode pad on the optical modulator chip side is GSSG, the shape of each electrode pad is the same even in a layout other than that in FIG. 5. In FIG. 5, in order to reduce the inductance of the wire, the signal electrode pads are connected by only two connection wires. From the viewpoint of reducing the inductance, it is also effective to use not only a configuration in which the wire is a ball wire as illustrated in the drawing but also a configuration in which the inductance of a wide ribbon wire or the like is further reduced.

Regarding the gap between the driver IC and the RF terrace in the circuit plane, since the influence of the inductance at these connection portions is smaller than the influence of the inductance between the driver IC and the optical modulator chip, for example, it is desirable to set this gap to 100 μm or less.

In the above description, the lenses 23 and 24 are mounted as the spatial optical components, but a fiber fixing member, a PBC, and the like are also included.

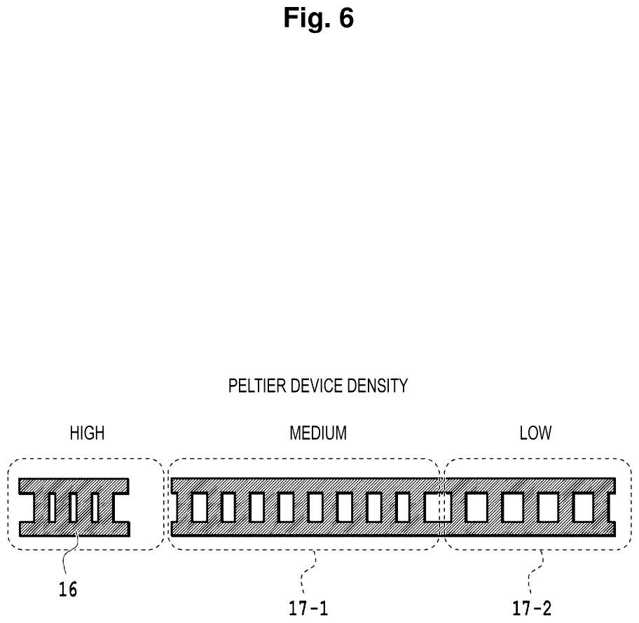

FIG. 6 is a diagram for describing density arrangement of the Peltier device in the optical transmitter of the present invention. In the Peltier device, a large number of n-type semiconductor elements and p-type semiconductor elements are disposed between the upper and lower metal surfaces to realize heat transfer between both surfaces as a whole. Therefore, the arrangement density of the semiconductor elements in the Peltier device can be set according to the heat generation amount of an object to be subjected to the temperature control. Considering the heat generation amount of each unit in the optical transmitter, the driver IC has the largest heat generation amount, and then the optical modulator chip and the spatial optical component are provided in this order. Specifically, the element densities of the Peltier devices are set such that the relationship of Mounting region of driver IC>Mounting region of optical modulator chip>Mounting region of spatial optical component is satisfied.

As illustrated in FIG. 6, the Peltier device 16 that controls the driver IC has the highest element density. Furthermore, in the Peltier device 17 that controls the optical modulator chip, a region immediately below the optical modulator may have a medium density, and a region 17-2 for the spatial optical component or the like may have a low density.

As described above in detail, the optical transmitter of the present invention can suppress the temperature dependency of optical modulation output characteristics and realize a novel configuration and an implementation form of the optical transmitter excellent in high speed.

### Industrial Applicability

The present invention can be used for an optical communication network.

1. An optical transmitter comprising:
an optical modulator;
a driver integrated circuit (driver IC) for supplying a modulation electrical signal for the optical modulator;
a first Peltier device for controlling a temperature of the optical modulator; and
a second Peltier device for controlling a temperature of the driver IC,
wherein the optical modulator and the driver IC are connected by a wire, and
the temperature of the second Peltier device is set to be lower than the temperature of the first Peltier device.

2. The optical transmitter according to claim 1, wherein a difference in height between an upper surface of the optical modulator mounted on the first Peltier device and an upper surface of the driver IC mounted on the second Peltier device is 100 μm or less.

3. The optical transmitter according to claim 1, wherein one side of the driver IC is mounted so as to protrude toward a chip side of the optical modulator with respect to a member immediately below the driver IC in a circuit plane,
one side of a chip of the optical modulator is mounted so as to protrude toward the driver IC side with respect to a member immediately below the chip in the circuit plane,
a gap between the one side of the driver IC and the one side of the chip of the optical modulator is 50 μm or less, and
a distance from the one side of the driver IC to an electrode pad is 50 μm or less and a distance from the one side of the chip of the optical modulator to the electrode pad is 50 μm or less.

4. The optical transmitter according to claim 3, wherein the member immediately below the driver IC is a metal block or a ceramic, and the member immediately below the chip is a subcarrier made of aluminum nitride (AlN).

5. The optical transmitter according to claim 1, wherein the temperature of the first Peltier device is set to 45±10° C., and
the temperature of the second Peltier device is set to 30±10°C.

6. The optical transmitter according to claim 1, wherein the optical modulator is made of InP,
at least one of an upper surface of the first Peltier device or an upper surface of the second Peltier device is made of aluminum nitride (AlN), and
a paste or a solder layer having thermal conductivity of 30 W/mK or more is provided between the first Peltier device and a chip of the optical modulator and between the second Peltier device and the driver IC.

7. The optical transmitter according to claim 1, wherein a spatial optical component is mounted on the first Peltier device on a side of a chip of the optical modulator opposite to the driver IC,
the first Peltier device and the second Peltier device respectively include an n-type semiconductor element and a p-type semiconductor element, and
in-plane densities of an the n-type semiconductor element and the p-type semiconductor element are set such that the in-plane density of the second Peltier device, the in-plane density of a mounting region of the chip of the optical modulator on the first Peltier device, and the in-plane density of a mounting region of the spatial optical component on the first Peltier device are in descent order.

8. The optical transmitter according to claim 1, wherein a chip of the optical modulator and the driver IC are mounted in a package of a high-speed driver integrated optical modulator (HB-CDM),
electrode pads with a differential signal interface are formed in an electrical signal path of each of an input unit of the package, the driver IC, and the chip of the optical modulator, and
a difference in height between an upper surface of an RF terrace on which a radio frequency (RF) electrode pad of the input unit is formed and an upper surface of the driver IC is 100 μm or less,
a gap between the RF terrace and the driver IC in a circuit plane is 100 μm or less, and
the RF electrode pad of the RF terrace and the electrode pad of the driver IC are connected by a wire.
